(19) United States
(12) Patent Application Publication
(10) Pub. No.: US 2007/0034932 A1
(43) Pub. Date: Feb. 15, 2007

(54) NOR flash memory devices and methods of fabricating the same

(75) Inventor: Jae-Hoon Kim, Osan-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/502,401

(22) Filed: Aug. 11, 2006

(30) Foreign Application Priority Data
Aug. 12, 2005 (KR) 10-2005-0074216

(51) Int. Cl. H01L 29/76

(52) U.S. Cl. 257/314

(57) ABSTRACT

A flash memory device includes active regions formed in a semiconductor substrate. The active regions include a cell array region, a high voltage transistor region and a low voltage transistor region. Gate structures are formed across the active regions, source and drain regions are formed at both sides of the gate structures in the active regions and lower spacers are formed at both sides of the gate structures. The lower spacer fills a space between the gate structures over the source region and is formed of a silicon oxide layer.

### PRIORITY STATEMENT

This non-provisional U.S. patent application claims priority under 35 U.S.C. § 119 to Korean patent application no. 10-2005-0074216, filed on Aug. 12, 2005 in the Korean Intellectual Property Office (KIPO), the entire contents of which is incorporated herein by reference.

### BACKGROUND

### Description of the Related Art

Semiconductor memory devices may be volatile or non-volatile according to whether or not power is required to retain stored information. Volatile memory devices, such as, dynamic random access memories (DRAMs) and static random access memories (SRAMs) have higher operating speeds, but require power to retain stored information. By contrast, non-volatile memory devices, such as, flash memories do not require power to retain stored information. As a result, non-volatile memory devices are being more widely used in portable electronic devices.

Improving integration of semiconductor memory devices may reduce costs. However, when semiconductor devices are fabricated with a higher degree of integration, a width of a word line and widths of intervals between adjacent word lines may decrease. This decreased word line width may exacerbate short channel effects. In addition, the decrease in interval widths between word lines may exacerbate electrical disturbances between adjacent cells. However, suppressing both short channel effects and electrical disturbances simultaneously may be difficult.

For example, to suppress short channel effects (e.g., punch-through due to the extension of a depletion region), transistors of a related art flash memory devices are provided with source and drain electrodes having a lightly-doped drain (LDD) structure. However, in these related art flash memory devices, a higher voltage (e.g., 12˜18 V) may be required to perform a write operation of the flash memory device. As a result, related art flash memory devices may require high voltage transistors that more effectively suppress punch-through or the like. To provide a high voltage transistor with improved suppression of punch-through, a separate double spacer process may be used increase an interval width between a higher concentration impurity region and a gate electrode of the high voltage transistor.

As illustrated in FIGS. 1A and 1B, in a related art double spacer process, gate patterns 20 may be formed on a semiconductor substrate 10. A low-concentration impurity region 30 may be formed using the gate patterns 20 as an ion mask in an ion injection process. A silicon nitride layer 40 and a silicon oxide layer may be sequentially stacked on a resulting structure. The silicon nitride layer 40 being deposited may have a thickness such that the source and drain electrodes have an LDD structure. However, the aforementioned decrease in intervals between the word lines may cause the silicon nitride layer 40 to fill a space 99 between adjacent word lines over a source region (S) of a cell array region (CAR).

An anisotropic etching process may be performed on the silicon oxide layer until the silicon nitride layer 40 is exposed. As a result, oxide layer spacers 50 may be formed on the silicon nitride layer 40 and at sidewalls of the gate pattern 20. A photoresist pattern 60 covering a high voltage transistor region (HVR) may be formed, and oxide layer spacers 50 in the cell array region (CAR) and a low voltage region (LVR) may be removed using the photoresist pattern 60 as an etching mask.

Referring to FIGS. 2A and 2B, the photoresist pattern 60 may be removed and an anisotropic etching process may be performed on the silicon nitride layer 40 until the semiconductor substrate 10 is exposed to form nitride layer spacers 45. The nitride layer spacers 45 in the high voltage transistor region (HVR) may be formed using the oxide layer spacers 50 remaining on the HVR as an etching mask. This may cause the nitride layer spacers 45 in the high voltage transistor region (HVR) to have greater widths than those of nitride spacers within other regions. An ion injection process using the nitride layer spacers 45 and the gate patterns 20 as an ion mask may be performed to form high-concentration impurity regions 70 in the semiconductor substrate 10.

A silicon nitride layer has a higher dielectric constant than a silicon oxide layer. As a result, when the silicon nitride layer 40 fills the space 99 between the word lines, electrical disturbance increase. Table 1 shows results of simulation for estimating of the electrical disturbance occurring in a related art NOR flash memory device. In this simulation, capacitances between a floating gate electrode (FG-0) of a reference cell and floating gate electrodes (FG-1˜FG-8) of adjacent cells were calculated with respect to first and second experimental groups to which different design rules are applied.

TABLE 1

| | First experimental group(F) | Second experimental group(F) |
|---|---|---|
| FG-1 | 1.60 × 10⁻²⁰ | 4.33 × 10⁻²¹ |
| FG-2 | 3.38 × 10⁻²⁰ | 8.97 × 10⁻²¹ |
| FG-3 | 1.59 × 10⁻²⁰ | 4.30 × 10⁻²¹ |
| FG-4 | 2.10 × 10⁻¹⁸ | 6.02 × 10⁻¹⁹ |
| FG-5 | 2.10 × 10⁻¹⁸ | 6.02 × 10⁻¹⁹ |
| FG-6 | 3.71 × 10⁻¹⁹ | 2.17 × 10⁻¹⁹ |
| FG-7 | 3.48 × 10⁻¹⁸ | 2.47 × 10⁻¹⁸ |
| FG-8 | 3.70 × 10⁻¹⁹ | 2.16 × 10⁻¹⁹ |

Referring to Table 1, the capacitance between the FG-0 cell and the FG-7 cell were more dominant. For example, the capacitance between the FG-0 cell and the FG-7 was 41%˜60% of the total capacitance between the reference cell (FG-0) and the adjacent eight cells (FG-1˜FG-8). As illustrated in FIG. 3A, a source line (SL) may be interposed between the FG-0 reference cell and the FG-7 cell, and as described above, the space 99 over the source region (S) may be filled with the silicon nitride layer. The dominant capacity between the FG-7 cell and the FG-0 reference cell may be interpreted as results of the filling of the space 99 over the source region (S) with the silicon nitride layer.

However, filling of the space 99 with the silicon nitride layer 40 may be difficult using related art methods because related art double spacer processes require sequentially stacking two spacer layers (e.g., a silicon nitride layer and a silicon oxide layer) having etching selectivity. In one example, if a silicon oxide layer and a silicon nitride layer, the spacer layers are sequentially stacked (e.g., with a different stacking order as compared to the aforementioned example), the double spacer process may include selectively removing nitride layer spacers from the low voltage transistor region (LVR) and the cell array region (CAR) (in this example, the nitride layer spacers are formed by etching the silicon nitride layer formed according to the changed stacking order). As described above, such selective removal may be performed using photoresist pattern 60 as an etching mask, but the photoresist pattern 60 may not have the etching selectivity with respect to an etching recipe (e.g., an etching solution containing phosphoric acid) used to remove the silicon nitride layer. Therefore, while the nitride layer spacers are removed from the cell array region (CAR) and the low voltage transistor region (LVR), the photoresist pattern 60 is also removed. As a result, the nitride layer spacers may be undesirably removed even from the HVR. For example, if the stacking order is changed, performing the selective removing operation may be difficult or even impossible.

Consequently, the related art double spacer process filling the space between word lines over the source region (S) of the cell array region (CAR) with the silicon nitride layer may not be suppressed because it may be more difficult (or even impossible) to selectively remove the photoresist pattern 60 and the silicon nitride layer.

### SUMMARY

Example embodiments relate to semiconductor devices and methods of fabricating the same. At least one example embodiment relates to a NOR flash memory device and a method of fabricating the same.

At least one example embodiment provides a method of fabricating a NOR flash memory device capable of suppressing and/or preventing a space between word lines from being filled with a silicon nitride layer. At least one example embodiment provides a method of fabricating a NOR flash memory device including a higher or high voltage transistor capable of suppressing and/or preventing the occurrence of punch-through. At least one example embodiment present invention provides a NOR flash memory device capable of suppressing and/or preventing a space between word lines from being filled with a silicon nitride layer. At least one example embodiment provides a NOR flash memory device including a higher or high voltage transistor capable of suppressing and/or preventing the occurrence of punch-through.

At least one example embodiment provides a method of fabricating a NOR flash memory device. In at least this example embodiment, spacers may be formed using an etch stop layer. For example, gate structures may be formed on a first region (e.g., a cell array region), a second region (e.g., a high voltage transistor region) and a third region (e.g., a low voltage transistor region) of a substrate. A lower spacer layer, an etch stop layer and an upper spacer layer with a conformal thickness may be formed sequentially on a resulting structure including the gate structures. Upper spacers may be formed at both sides of the gate structures by etching the upper spacer layer until an upper surface of the etch stop layer is exposed. The upper spacers may be removed from the cell array region and the low voltage transistor region while leaving the upper spacers in the high voltage transistor region. Etch stop layer patterns may be formed interposed between the upper spacers and the lower spacers by etching the etch stop layer using the upper spacers as an etching mask until the lower spacer layer is exposed. Lower spacers may be formed at both sides of the gate structures by anisotropically etching the exposed lower spacer layer until an upper surface of the semiconductor substrate is exposed.

In at least some example embodiments, the etch stop layer may be formed of one of a silicon nitride layer and a silicon oxynitride layer, the upper spacer layer may be formed of one of a silicon oxide layer and a polycrystalline silicon layer, and the lower spacer layer may be formed of a silicon oxide layer.

In at least some example embodiments, the forming of the lower spacers may include forming ‘L’ shaped lower spacers in the high voltage transistor region by anisotropically etching the lower spacer layer using the upper spacers of the high voltage transistor as an etching mask, each lower spacer being interposed between the upper spacer and the gate structure and between the upper spacer and the semiconductor substrate. The ‘L’ shaped lower spacers formed in the high voltage transistor region may have widths greater than those of the lower spacers formed in the cell array region and the low voltage transistor region.

At least some example embodiments provide a NOR flash memory device in which a spacer formed of a silicon oxide layer fills a space between word lines. In at least one example embodiment, the NOR flash memory device may include active regions formed in a semiconductor substrate including a cell array region, a high voltage transistor region and/or a low voltage transistor region. Gate structures may be formed across the active regions, and source and drain regions may be formed at both sides of the gate structures in the active regions. Lower spacers may be formed of a silicon oxide layer at both sides of the gate structures. The lower spacer over the source region of the cell array region may fill a space between the gate structures.

In at least some example embodiments, the lower spacers formed in the high voltage transistor region may have widths greater than those of the lower spacers formed in the cell array region and the low voltage transistor region.

### BRIEF DESCRIPTION OF THE DRAWINGS

Example embodiments will be described with reference to the attached drawings in which:

FIGS. 1A and 1B, and FIGS. 2A and 2B are cross-sectional views for describing a related art method of fabricating a NOR flash memory device;

FIG. 3A is a plan view illustrating one portion of a cell array of a NOR flash memory device;

FIG. 3B is a plan view illustrating a high voltage transistor of a NOR flash memory device, according to an example embodiment of the present invention;

FIG. 3C is a plan view illustrating a low voltage transistor of a NOR flash memory device, according to an example embodiment of the present invention;

FIGS. 4A through 10A are cross-sectional views taken along line I-I′ of FIG. 3A, and describing a method of fabricating a NOR flash memory device, according to an example embodiment of the present invention; and

FIGS. 4B through 10B are cross-sectional views taken along lines II-II′ and III-III′ of FIGS. 3B and 3C, and describing a method of fabricating a NOR flash memory device, according to an example embodiment of the present invention.

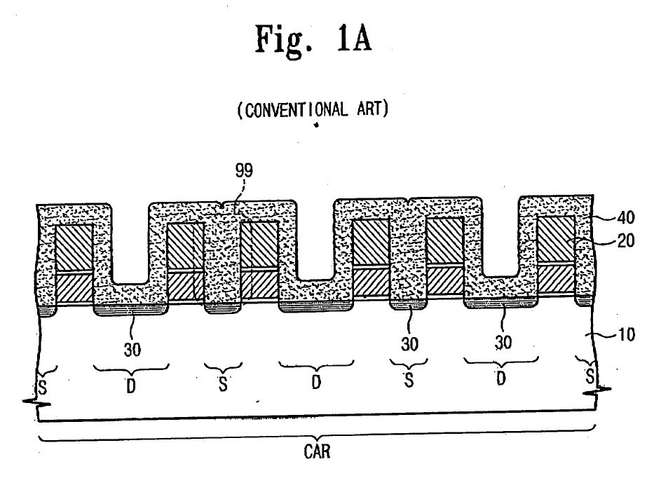

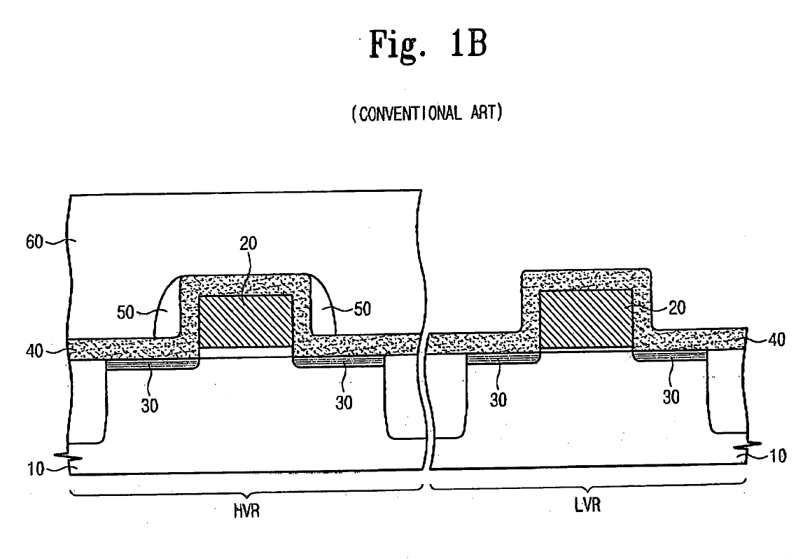

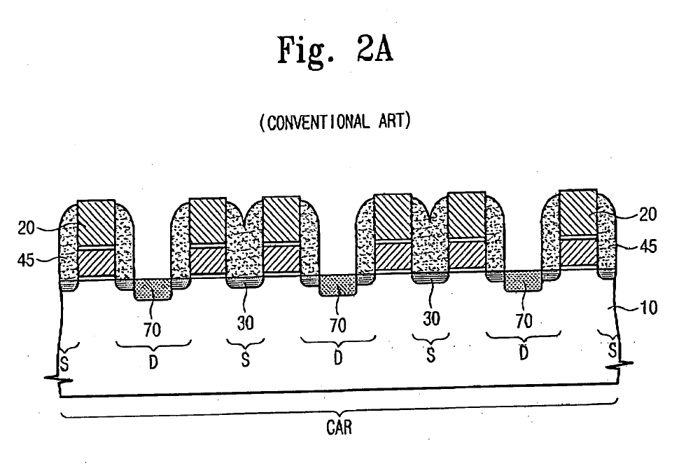

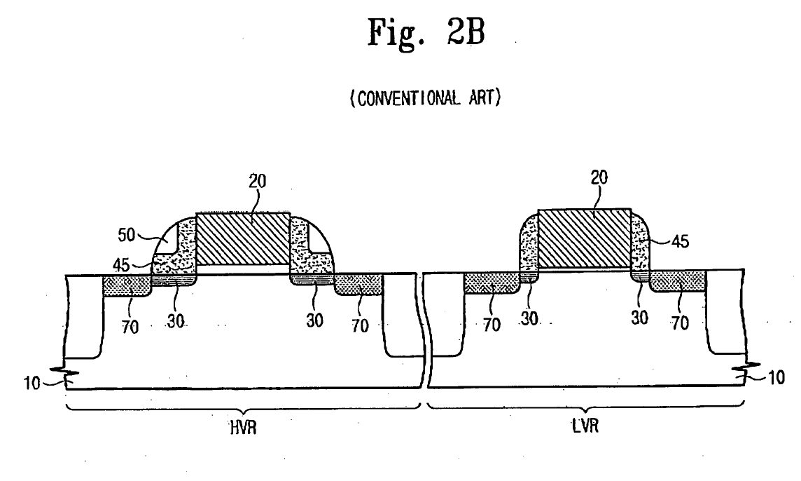

### DETAILED DESCRIPTION OF EXAMPLE EMBODIMENTS

Various example embodiments of the present invention will now be described more fully with reference to the accompanying drawings in which some example embodiments of the invention are shown. In the drawings, the thicknesses of layers and regions are exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

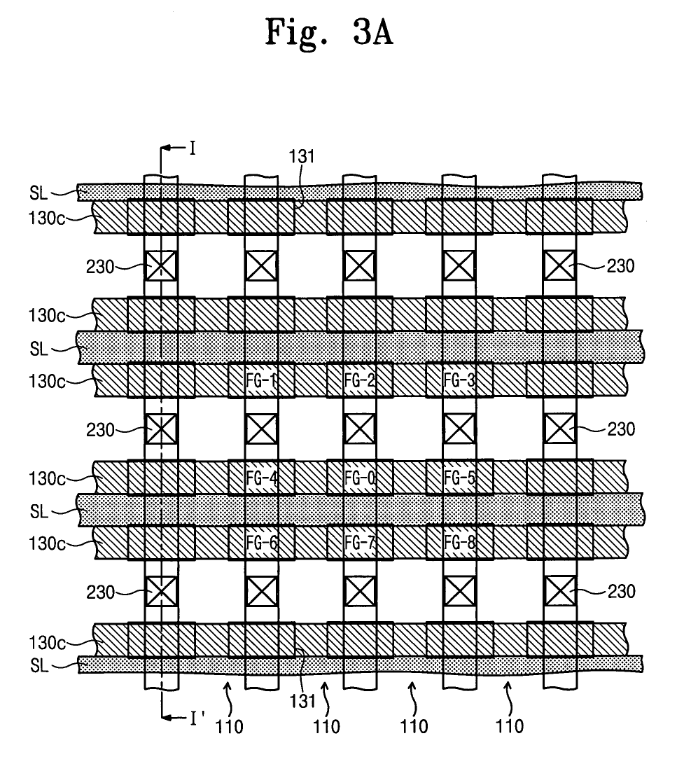

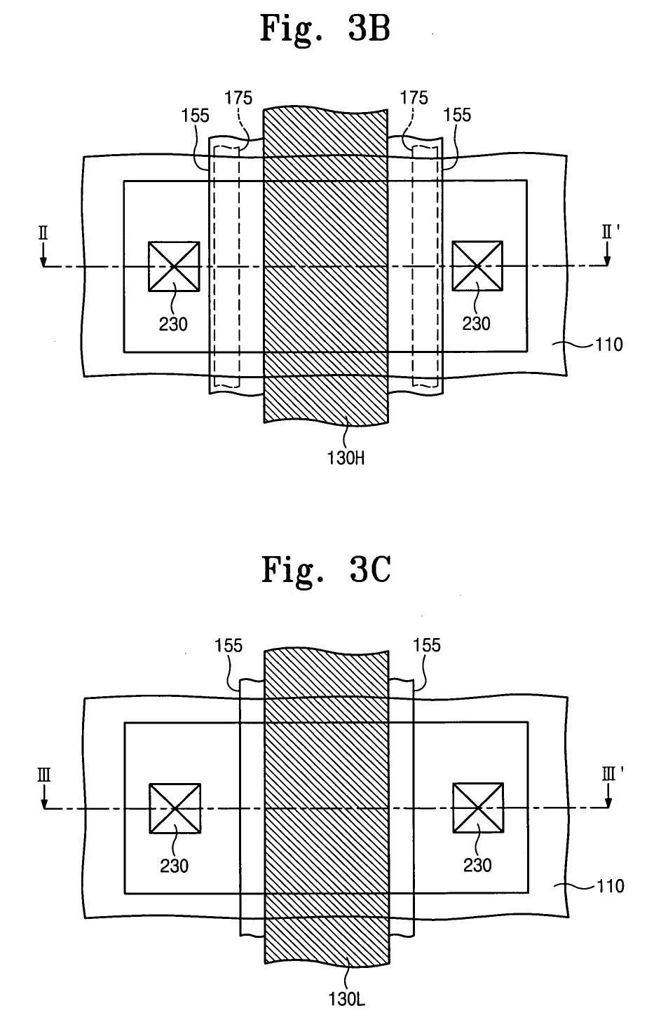

As discussed above, FIG. 3A is a plan view illustrating portions of a cell array region of a NOR flash memory device. Example embodiments as described herein may be implemented in a cell array such as the cell array shown in FIG. 3A.

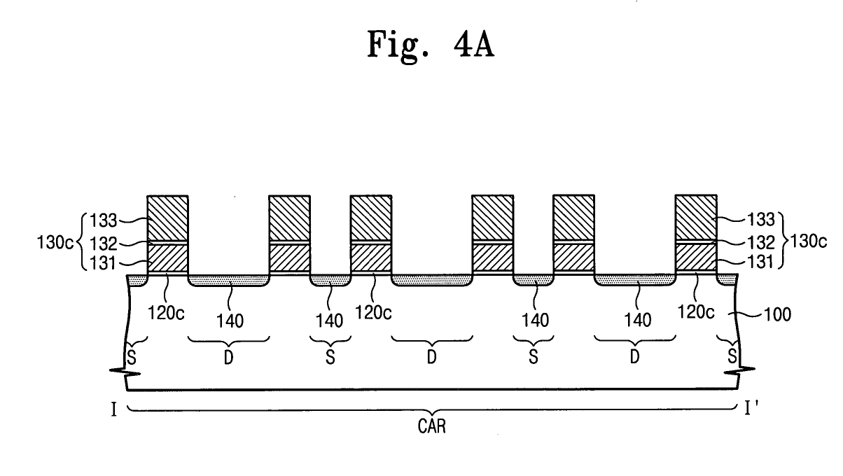

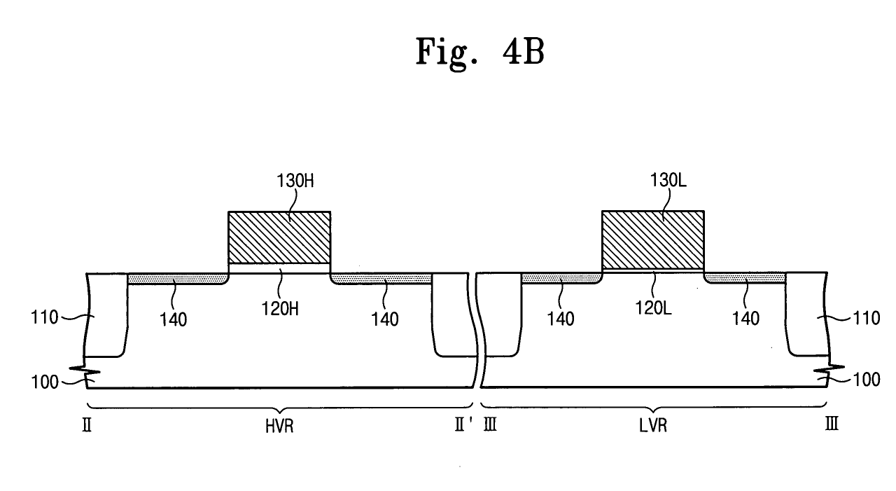

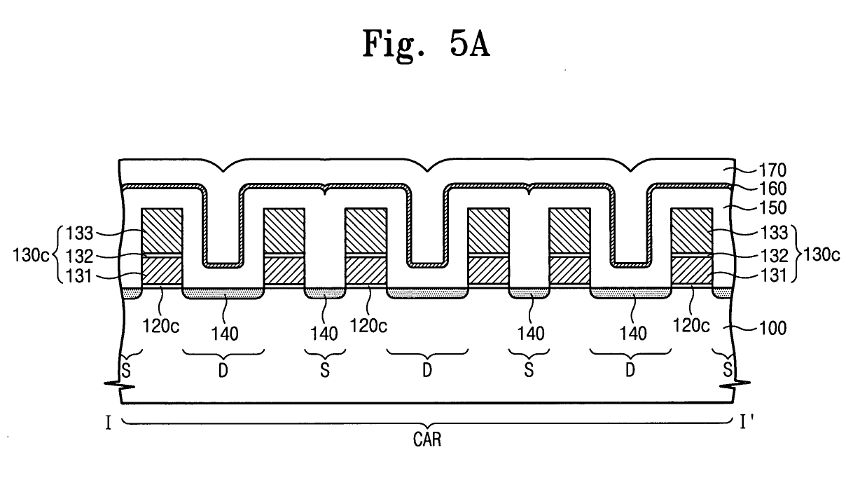

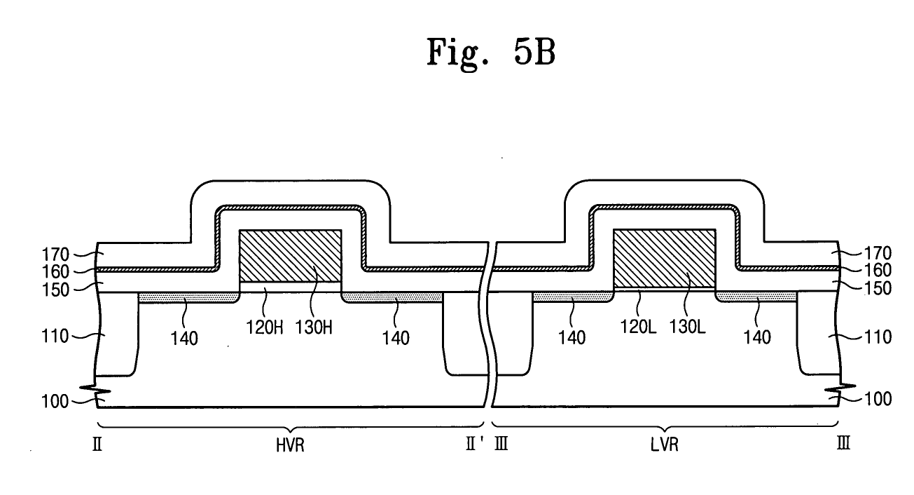

FIGS. 3B through 3C are plan views illustrating portions of a high voltage transistor region and a low voltage transistor region of a NOR flash memory, respectively, according to an example embodiment of the present invention. FIGS. 4A through 10A are cross-sectional views taken along line I-I′ of FIG. 3A and FIGS. 4B through 10B are cross-sectional views taken along lines II-II′ and III-III′ of FIGS. 3B and 3C, respectively.

Referring to FIGS. 4A and 4B, device isolation layer patterns 110 defining active regions maybe formed in a semiconductor substrate 100. The semiconductor substrate 100 may be divided into a cell array region (CAR), a high voltage transistor region (HVR) and a low voltage transistor region (LVR) by device isolation layer patterns 110. A gate insulating layer may be formed on the active regions. The gate insulating layer may include a cell gate insulating layer 120C formed in the cell array region (CAR), a high voltage gate insulating layer 120H formed on the high voltage transistor region (HVR) and a low voltage gate insulating layer 120L formed on the low voltage transistor region (LVR). The high voltage gate insulating layer 120H may have a thickness greater than the thickness of the cell gate insulating layer 120C and the low voltage gate insulating layer 120L. According to at least one example embodiment, the cell gate insulating layer 120C may have a thickness smaller than that of the low voltage gate insulating layer 120L.

Gate patterns may be formed on a resulting structure including the gate insulating layer across the active regions. The gate patterns may include cell gate patterns 130C formed across the active region in the cell array region (CAR), high voltage gate patterns 130H formed across the active region in the high voltage transistor region (HVR) and low voltage gate patterns 130L formed across the active region in the low voltage transistor region (LVR).

The cell gate pattern 130C may include a floating gate electrode 131, an inter-gate insulating layer pattern 132 and a control gate electrode 133. The floating gate electrode may be an electrically-isolated electric conductor for storing information. The inter-gate insulating layer pattern 132 may be formed across the active regions on the floating gate electrode 131 such that a silicon oxide layer, a silicon nitride layer and a silicon oxide layer are stacked, for example, sequentially. The floating gate electrode 131 and the control gate electrode 133 may be formed of, for example, polycrystalline silicon. However, any similar and/or suitable material may be used.

According to at least one example embodiment, cell gate patterns 130C may be formed, and subsequently, high voltage gate pattern 130H and low voltage gate pattern 130L may be formed. In at least this example embodiment, high voltage gate pattern 130H and low voltage gate pattern 130L may be formed of layers having different physical properties from the cell gate patterns 130C. For example, high voltage gate pattern 130H and low voltage gate pattern 130L may be different in thickness, impurity concentration and/or conductivity from the cell gate pattern 130C. Also, according to at least this example embodiment, the process order of forming the gate insulating layer may be changed. For example, after the cell gate insulating layer 120C and the cell gate pattern 130C are formed, the high voltage insulation layer 120H and low voltage insulation layer 120L may be formed using a thermal oxidization process.

According to at least one other example embodiment, high voltage gate pattern 130H and low voltage gate pattern 130L may be formed by forming the floating gate electrode 131 or the control gate electrode 133. In at least this example embodiment, at least one layer used as the floating gate electrode 131, the inter-gate insulating layer pattern 132 and the control gate electrode 133 may be etched in the high voltage transistor region (HVR) and low voltage transistor region (LVR) using a patterning process.

After the gate patterns are formed, an ion injection process using the gate patterns as a mask may be performed to form low-concentration impurity regions 140 in the semiconductor substrate 100. The low-concentration impurities regions 140 may be formed each side of gate patterns 130C in the active region, and may be used as source and drain electrodes of a transistor. In at least this example embodiment, the widths of the low-concentration impurity regions 140 in the cell array region (CAR) may be determined by the intervals between the cell gate patterns 130C because a plurality of cell gate patterns 130C may be disposed parallel or substantially parallel to each other at an upper portion of the cell array region (CAR).

According to at least some example embodiments, a low-concentration impurity region (hereinafter, referred to as source region (S)) used as a source electrode in the cell array region (CAR) may be narrower than a low-concentration impurity region (hereinafter, referred to as drain region (D)) used as a drain electrode in the cell array region (CAR). Consequently, as shown in FIG. 3A, the intervals between the cell gate patterns 130C may be greater in the source region (S) than in the drain region (D).

According to at least one example embodiment, before or after the low-concentration impurity regions 140 are formed, a source line forming process may be used to form a source line connecting the low-concentration impurity regions 140 of the source regions (S) in a direction of the cell gate pattern 130C. The source line forming process may include forming a photoresist pattern (not shown) covering the drain region (D) while exposing the source region (S) and removing a device isolation layer pattern 110 adjacent to the source region (S) using the photoresist pattern as an etching mask. This exposes the semiconductor substrate 100 under the removed isolation layer pattern 110. A high-concentration ion injection process, using the photoresist pattern as an ion injection mask, may be performed to form a source line (SL) electrically connecting the exposed semiconductor substrate 100 to the source region (S).

Referring to FIGS. 5A and 5B, a lower spacer layer 150, an etch stop layer 160 and an upper spacer layer 170 may be formed (e.g., sequentially formed) to cover a resulting structure including the gate patterns. The lower spacer layer 150, the etch stop layer 160 and the upper spacer layer 170 may be formed, for example, with a conformal thickness. The lower spacer layer 150 may be formed of a material having a dielectric constant less than or equal to that of at least a silicon nitride layer. For example, the lower spacer layer 150 may be a silicon oxide layer formed using low pressure chemical vapor deposition (LP-CVD); however, the lower spacer layer 150 may be formed of any suitable material using any suitable process. The upper spacer layer 170 may be a silicon oxide layer, a polycrystalline silicon layer, or the like. The etch stop layer 160 may be formed of a material having etching selectivity with respect to the lower spacer layer 150 and the upper spacer layer 170. For example, the etch stop layer 160 may be a silicon nitride layer, a silicon oxynitride layer or the like.

According to at least one example embodiment, the lower spacer layer 150 may be formed to fill a space between the cell gate patterns 130C over the source region (S) in the cell array region (CAR). However, the lower spacer layer 150 may not completely fill (e.g., partially fill) a space between the cell gate patterns 130C over the drain region (D). As described above, this may be achieved by controlling a deposition thickness of the lower spacer layer 150 because the drain region (D) may be greater than the source region (S) of the cell array region (CAR). For example, the lower spacer layer 150 may be deposited, for example, with a thickness greater than or equal to about half of the width of the source region (S) of the cell array region (CAR) and less than or equal to about half of the width of the drain region (D).

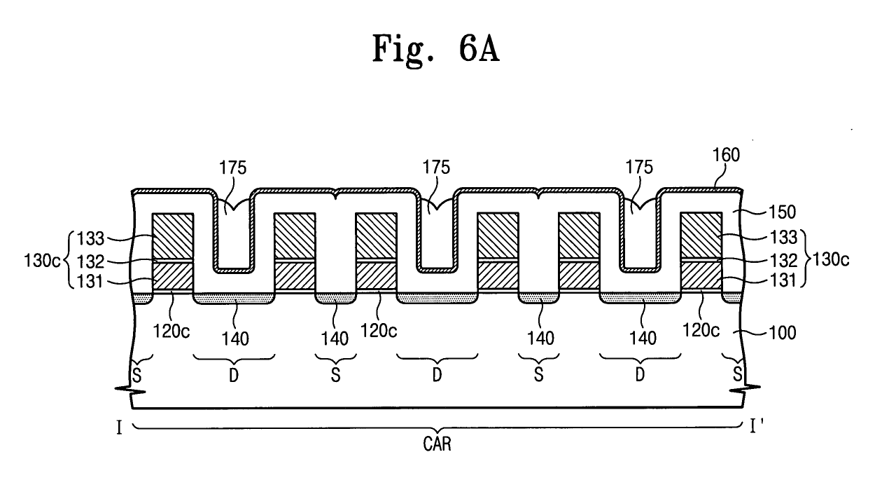

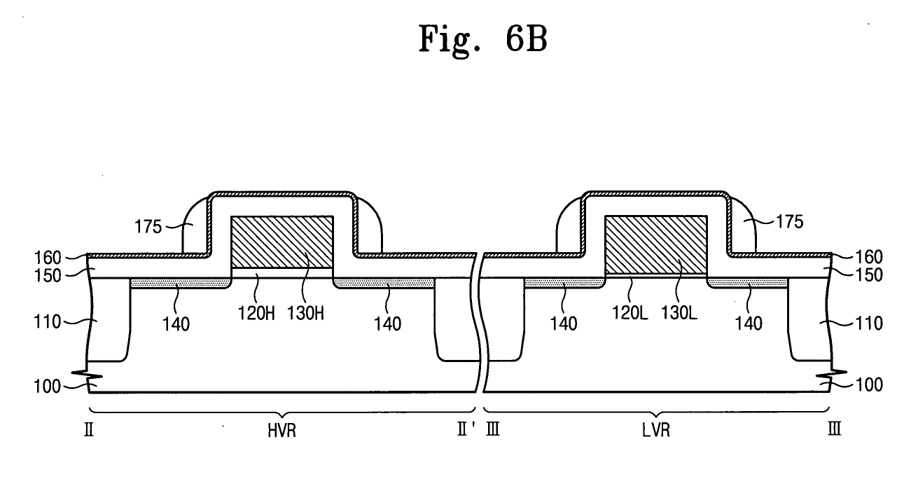

Referring to FIGS. 6A and 6B, the upper spacer layer 170 may be anisotropically etched until an upper surface of the etch stop layer 160 is exposed. In this example, the upper spacer layer 170 may be etched to about the deposition thickness thereof, or may be over-etched. Accordingly, upper spacers 175 may be formed at sidewalls of the gate patterns to cover the etch stop layer 160.

As described above, the lower spacer layer 150 may fill a space between the cell gate patterns 130C over the source region of the cell array region (CAR) and the upper spacers 175 may not be formed in this region. If the upper spacer layer 170 is deposited with a greater thickness, the upper spacer layer 170 may fill a space between the cell gate patterns 130C over the drain region (D) of the cell array region (CAR). In this example, the upper spacers 175 may fill the space between the cell gate patterns 130C. In comparison, upper spacers 175 formed in both the high voltage transistor region (HVR) and the low voltage transistor region (LVR) may have the same or substantially the same structure.

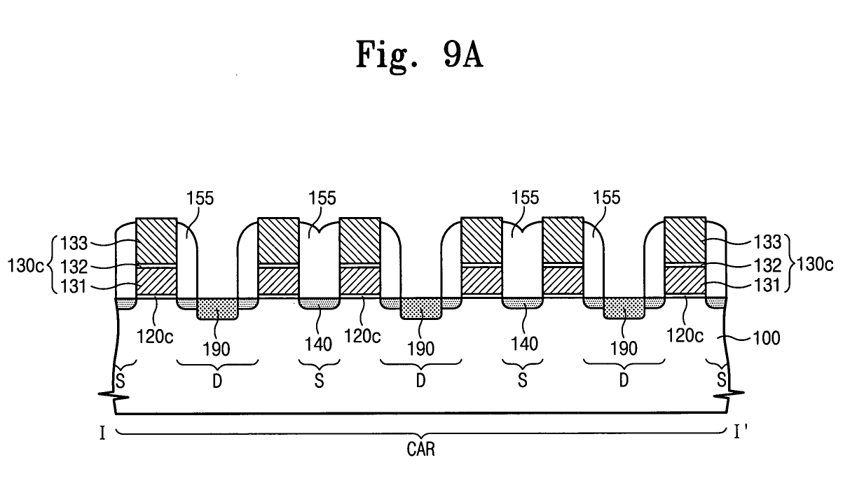

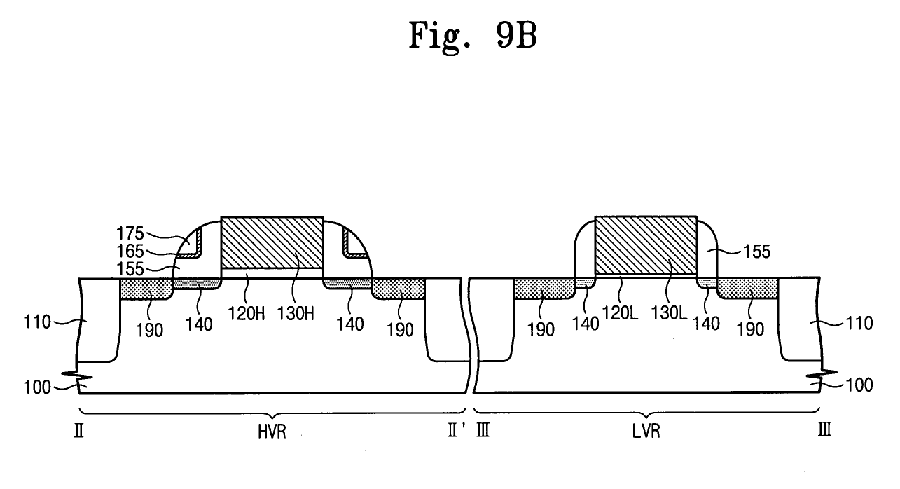

The width of the upper spacer 175 formed in the high voltage transistor region (HVR) may determine a structure of source and/or drain electrodes of a high voltage transistor because the width of the upper spacer 175 may determine an interval between the high voltage gate pattern 130H and the high-concentration impurity region 190 in the subsequent process of forming a high-concentration impurity region (e.g., 190 of FIG. 9B). Such a width of the upper spacer 175 may be controlled by changing the deposition thickness of the upper spacer layer 170.

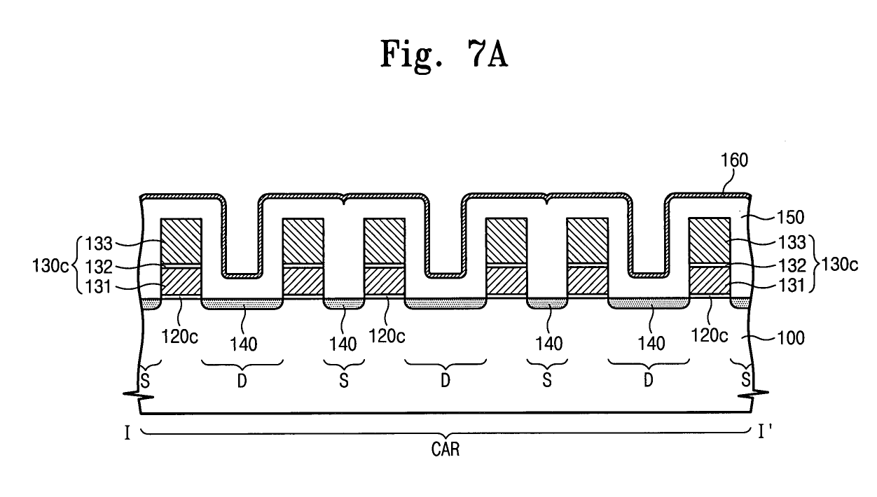

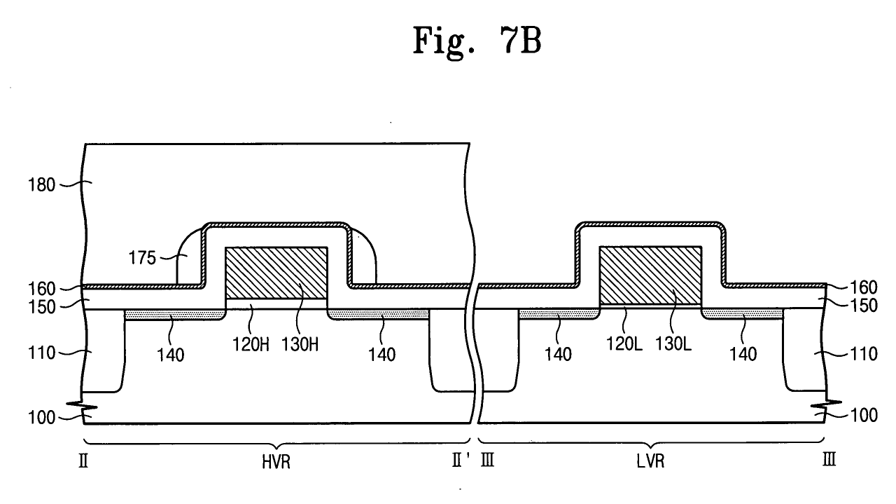

Referring to FIGS. 7A and 7B, a photoresist pattern 180 covering the high voltage transistor region (HVR), while exposing the low voltage transistor region (LVR) and the cell array region (CAR) may be formed. The upper spacers 175 may be removed from the low voltage transistor region (LVR) and the cell array region (CAR) using the photoresist pattern 180 as an etching mask. In at least this example operation, the exposed upper spacers 175 may be removed using, for example, wet etching with an etching solution having etching selectivity with respect to the etch stop layer 160.

When the upper spacer 175 and the etch stop layer 160 are formed of a silicon oxide layer and a silicon nitride layer, respectively, an etching solution containing fluoric acid may be used in the above-described operation of removing the upper spacers 175. However, similar etching solutions may also be used. The photoresist pattern 180 may have an etch-proof property with respect to the fluoric acid, and using an etching solution containing the fluoric acid may enable selective removal of the upper spacers 175 from the low voltage transistor region (LVR) and the cell array region (CAR), while suppressing damage to the high voltage transistor region (HVR).

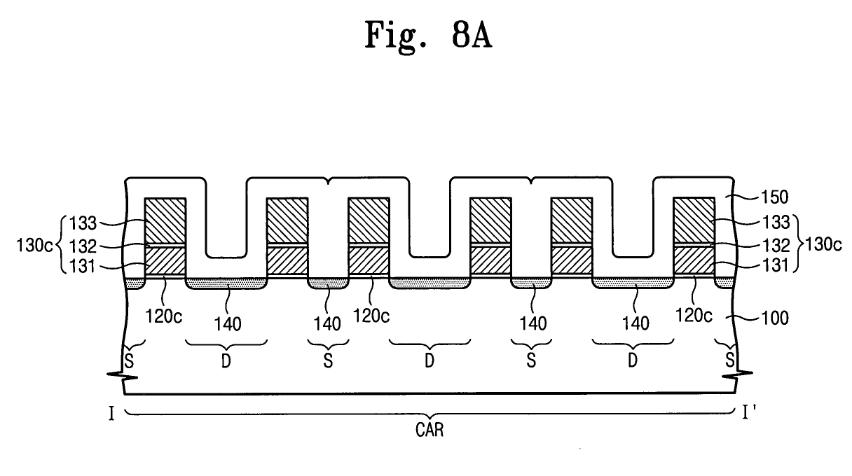

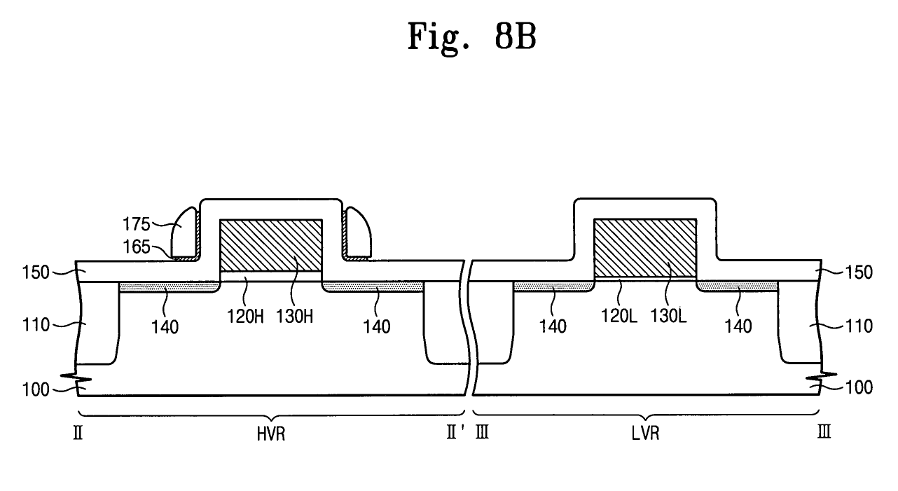

Referring to FIGS. 8A and 8B, the photoresist pattern 180 may be removed to expose the upper spacers 175 from the high voltage transistor region (HVR). In at least this example, the etch stop layer 160 may cover the entire surface of the semiconductor substrate and the upper spacers 175 may remain on the etch stop layer 160 at each side of the gate pattern of the high voltage transistor region (HVR).

The etch stop layer 160 may be etched until the lower spacer layer 150 is exposed to form an etch stop layer pattern 165 between the upper spacer 175 and the lower spacer layer 150. In at least this example embodiment, the etch stop layer pattern 165 may be formed as an ‘L’ shape. This example operation may include using an etching solution having an etching selectivity with respect to the lower spacer layer 150 and the upper spacer 175. In addition, this example operation may be performed using, for example, wet etching or the like. According to at least one example embodiment, an etching solution containing, for example, phosphoric acid may be used because the photoresist pattern 180 has been removed. However, similar etching solutions may also be used in the alternative.

Referring to FIGS. 9A and 9B, the lower etch stop layer 160 may be anisotropically etched until the semiconductor substrate 100 is exposed to form lower spacers disposed on side walls of the gate patterns. In at least this example, the etching may be performed using an etching solution having the etching selectivity with respect to the semiconductor substrate 100 and the gate pattern. In at least this example, the upper spacers 175 and the etch stop layer patterns 165 may be used as an etching mask and as illustrated, the lower spacers 155 may be recessed at a desired or given thickness.

The lower spacers 155 may have different shapes depending on position because of methods, according to example embodiments, as described above. For example, the lower spacer 155 of the high voltage transistor region (HVR) may have an ‘L’ shape because the lower spacer 155 may be formed using the upper spacer 175 as an etching mask. In at least one example, the lower spacer 155 of the high voltage transistor region (HVR) may have a vertical or substantially vertical portion disposed on a sidewall of the high voltage gate pattern 130H and a horizontal or substantially horizontal portion extending outward from a lower part of the vertical portion. The vertical portion may be disposed between the high voltage gate pattern 130H and the upper spacer 175, and the horizontal portion may be disposed between the upper spacer 175 and the semiconductor substrate 100.

In comparison, the lower spacers 155 formed in the low voltage transistor region (LVR) and the drain region (D) of the cell array region (CAR) may have a general spacer shape as illustrated in the figures. Because the lower spacer layer 150 fills a space between the cell gate patterns 130C over the source region (S) of the cell array region (CAR) as described above, the lower spacer 155 formed over this region may fill the space between the gate cell patterns 130C. According to at least this example, the lower spacer 155 may be formed of, for example, a silicon oxide layer, and example embodiments may help suppress and/or prevent electrical disturbances due to a larger dielectric constant associated with a silicon nitride layer.

According to at least one example embodiment, after the gate patterns are formed, a thermal oxidization process may be used to repair damage resulting from etching. In at least this example, a thermal oxide layer (not shown) may be interposed between the lower spacer 155 and the gate patterns.

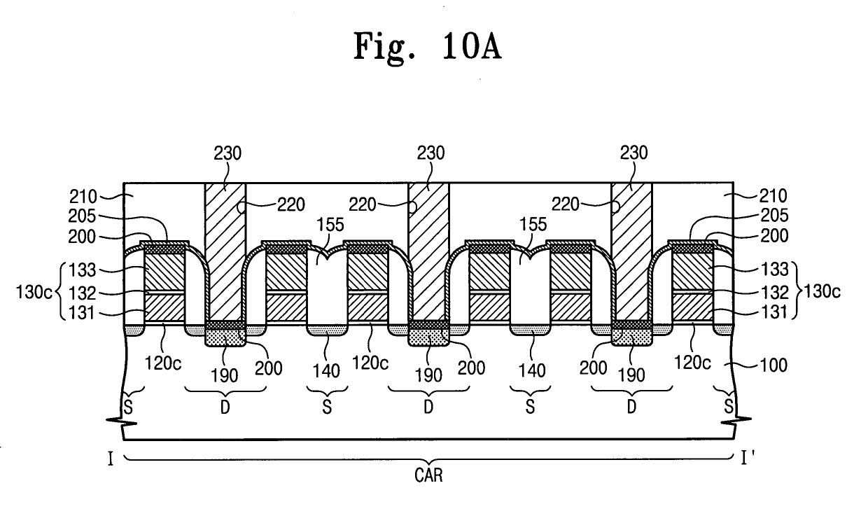

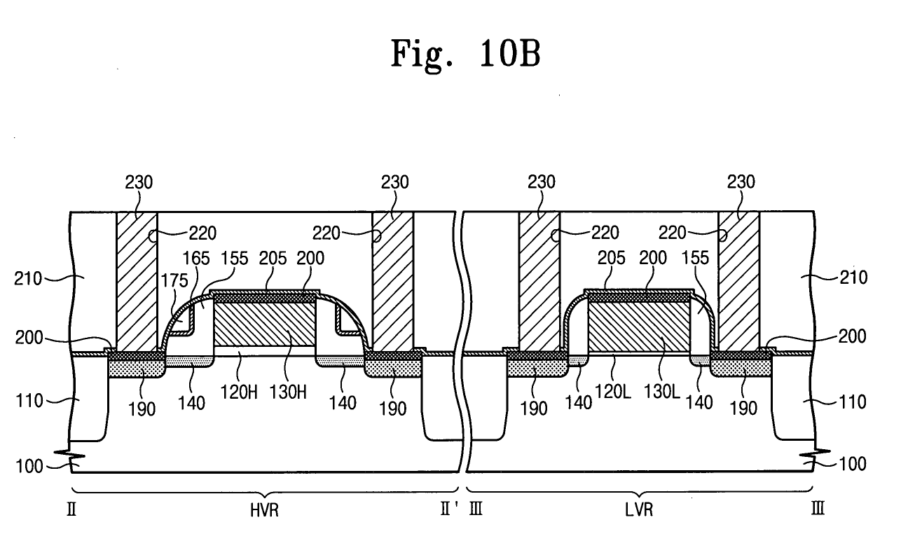

Referring to FIGS. 10A and 10B, an ion injection process may be performed using the gate patterns and the lower spacers 155 as an ion mask to form high-concentration impurity regions 190 in the exposed semiconductor substrate 100. The low-concentration impurity regions 140 and the high-concentration impurity regions 190 may be used as source and drain electrodes of a transistor.

The high-concentration impurity regions 190 may be spaced apart from the gate patterns because the lower spacers 155 may be used as an ion mask. In at least this example, the distance between the high-concentration impurity region 190 and the gate pattern may be determined by the width of the lower spacer 155. As a result, the source and drain electrodes may have a lightly doped drain (LDD) structure. However, the high-concentration impurity region 190 may not be formed over the source region of the cell array region (CAR) because the lower spacers 155 fill the space between the gate patterns. As described with reference to FIG. 4A, for example, the source region of the cell array region (CAR), according to at least one example embodiment, has an impurity concentration determined by impurities injected during the separate source line forming process.

As described above, the lower spacers 155 of the high voltage transistor region (HVR) may have widths greater than those of the lower spacers 155 of other regions because of the upper spacer 175.

Consequently, the distance between the high-concentration impurity region and the gate pattern of this region may be longer than that in other regions. A longer distance there between may increase a breakdown voltage of the high voltage transistor.

A selective silicide forming process may be performed on a resulting structure including the high-concentration impurity regions 190 to form silicide patterns 200 on the high-concentration impurity regions 190 and the gate patterns.

Thereafter, an inter-layer insulating layer 210 may be formed on a resulting structure including the silicide patterns 200, and patterning may be performed thereon so that contact holes 220 exposing upper surfaces of the silicide patterns 200 are formed. The contact holes 220 may be formed on the gate patterns or on given regions of the source line of the cell array region (CAR). The inter-layer insulating layer 210 may be formed, for example, of a silicon oxide layer or the like. Contact plugs 230 may be embedded in the contact holes 220. An etching stop layer 205 may be formed on a resulting structure including the silicide patterns 200 to suppress and/or prevent short-circuiting between the contact plug 230 and the gate pattern, which may occur due to misalignment in the contact hole forming process.

According to at least some example embodiments, a double spacer process may improve properties of a high voltage transistor by using a lower spacer layer, an etch stop layer and an upper spacer layer stacked sequentially. In at least this example, the lower spacer layer may be formed of a material (e.g., a silicon oxide layer or the like) having a dielectric constant lower than that of a silicon nitride layer. As a result, the lower spacer layer may fill a space between word lines over a source region of a cell array region, and the double spacer process may be performed, without filling the space between the word lines with a silicon nitride layer. For example, at least some example embodiments may improve properties of the high voltage transistor while suppressing and/or preventing electrical disturbances between the word lines.

It will be apparent to those skilled in the art that various modifications and variations can be made to example embodiments of the present invention. Thus, it is intended that example embodiments of the present invention cover the modifications and variations thereof provided they come within the scope of the appended claims and their equivalents.

What is claimed is:

1. A method of fabricating a memory device, the method comprising:
forming a plurality of gate structures on a first region, a second region and a third region of a substrate;
forming a lower spacer layer, an etch stop layer and an upper spacer layer on a resultant structure including the gate structures;
patterning the upper spacer layer to form an upper spacer at each side of each gate structure;
removing the upper spacers from the first region and the third region;
forming etch stop layer patterns between the upper spacers and the lower spacers on the second region by patterning the etch stop layer on the second region using the upper spacers as an patterning mask; and
patterning the exposed lower spacer layer in each of the first, second and third regions to form a lower spacer at each side of the gate structures in the first, second and third regions.

2. The method of claim 1, wherein the lower spacer at each side of the gate structures in the first, second and third regions is formed by anisotropically etching the exposed lower spacer layer in each of the first, second and third regions.

3. The method of claim 1, wherein the etch stop layer is formed of a material having etching selectivity with respect to the upper spacer layer.

4. The method of claim 1, wherein the etch stop layer is formed of one of a silicon nitride layer and a silicon oxynitride layer.

5. The method of claim 1, wherein the upper spacer layer is formed of one of a silicon oxide layer and a polycrystalline silicon layer.

6. The method of claim 1, wherein the lower spacer layer is formed of a silicon oxide layer.

7. The method of claim 1, wherein the forming of the gate structures includes,
forming a plurality of cell gate patterns parallel to each other in the first region, and
forming peripheral circuit gate patterns in the second and third regions.

8. The method of claim 1, wherein after the formation of the gate structures, the method further includes,
forming source and drain regions at sides of the gate structures in the substrate using ion injection process using the gate structures as a mask, the source region having a width smaller than that of the drain region in the first region.

9. The method of claim 8, wherein the lower spacer layer is formed to fill a space between the gate structures above the source region in the first region.

10. The method of claim 8, wherein the lower spacer layer is formed with a thickness greater than or equal to half of a width of a source region in the first region.

11. The method of claim 1, wherein the removing of the upper spacers from the first region and the third region includes,
forming a mask pattern exposing the first region and the third region while covering the second region including the upper spacers,
isotropically removing the upper spacers from the first region and the third region, using the mask pattern as an etching mask, and
removing the mask pattern to expose the upper spacers from the second region.

12. The method of claim 1, wherein the forming of the etch stop layer patterns includes,
isotropically etching the etch stop layer using the upper spacers in the second region as an etching mask, the etch stop layer having an etching selectivity with respect to the lower spacer layer.

13. The method of claim 1, wherein the forming of the lower spacers includes,
anisotropically etching the lower spacer layer using the upper spacers of the second region as an etching mask to form ‘L’ shaped lower spacers in the second region, each ‘L’ shaped lower spacer being interposed between the upper spacer and the gate structure and between the upper spacer and the substrate, wherein
the ‘L’ shaped lower spacers formed in the second region have widths greater than those of the lower spacers formed in the first region and the second region.

14. The method of claim 1, wherein the lower spacer is formed to fill a space between the gate structures above the source region of the first region, the lower spacer being formed of a silicon oxide layer.

15. The method of claim 1, wherein the lower spacer is formed to expose an upper surface of the drain region in the first region.

16. The method of claim 1, further including,
forming silicide patterns on the gate structures, on the source regions of the second and third regions and the drain regions of the first, second and third regions after the lower spacers are formed.

17. A flash memory device comprising:
a plurality of active regions formed in a first region, a second region and a third region of a substrate;
gate structures formed across the plurality of active regions;
source and drain regions formed at each side of the gate structures in the plurality of active regions; and
lower spacers formed at each side of the gate structures and formed of a silicon oxide layer, the lower spacers filling spaces between the gate structures above the source regions of the first region.

18. The device of claim 17, wherein each lower spacer formed in the second region has a width greater than or equal to widths of the lower spacers formed in the first region and the second region.

19. The device of claim 17, wherein the lower spacer formed in the second region includes a vertical portion disposed on a sidewall of the gate structure and a horizontal portion extending from a lower part of the vertical portion toward an adjacent gate structure.

20. The device of claim 19, further including,
an upper spacer disposed on the horizontal portion of the lower spacer in the second region, and
a ‘L’ shaped etch stop layer pattern interposed between the upper spacer and the lower spacer in the second region.

21. The device of claim 20, wherein the etch stop pattern is formed of one of a silicon nitride layer and a silicon oxynitride layer, and the upper spacer is formed of a silicon oxide layer and a polycrystalline silicon layer.

22. The device of claim 17, further including,
silicide patterns formed on source regions of the second and third regions, and drain regions of the first, second and third regions.

23. A flash memory device comprising:
a plurality of active regions formed in a first region, a second region and a third region of a substrate;
gate structures formed across the plurality of active regions;
source and drain regions formed at each side of the gate structures in the plurality of active regions;
lower spacers formed at each side of the gate structures, the lower spacers filling spaces between the gate structures above the source regions of the first region; and
an upper spacer formed on each lower spacer in the second region, but not on the lower spacers formed in the first and third regions.
